(19) United States
(12) Patent Application Publication
(10) Pub. No.: US 2019/0348305 A1
(43) Pub. Date: Nov. 14, 2019

(54) Rapid Wafer Drying Using Induction Heating

(71) Applicant: Tokyo Electron Limited, Tokyo (JP)

(72) Inventors: Derek Bassett, Austin, TX (US); Antonio Rotondaro, Austin, TX (US)

(21) Appl. No.: 16/407,073

(22) Filed: May 8, 2019

Related U.S. Application Data
(60) Provisional application No. 62/668,841, filed on May 9, 2018.
(60) Provisional application No. 62/689,302, filed on Jun. 25, 2018.

(51) Int. Cl. H01L 21/67

(52) U.S. Cl. CPC H01L 21/67034; H01L 21/67098

(57) ABSTRACT

A process and apparatus are provided in which substrate drying is accomplished by rapid boiling of the surface liquid to vaporize the liquid before it can cause capillary pattern collapse to occur. More specifically, electromagnetic induction heating is utilized to provide an oscillating magnetic field transverse to the substrate surfaces to induce electrical eddy currents in the substrate that cause the substrate to rapidly heat up. The liquid will then vaporize quickly without causing pattern collapse. Such techniques are particularly useful for IPA drying.

### CROSS-REFERENCE TO RELATED APPLICATIONS

This application claims priority to U.S. Provisional Patent Application No. 62/668,841, entitled, “Rapid Wafer Drying Using Induction Heating,” filed May 9, 2018; the disclosure of which is expressly incorporated herein, in its entirety, by reference. This application claims priority to U.S. Provisional Patent Application No. 62/689,302, entitled, “Rapid Wafer Drying Using Induction Heating,” filed Jun. 25, 2018; the disclosure of which is expressly incorporated herein, in its entirety, by reference.

### BACKGROUND

The present disclosure relates to the processing of substrates. In particular, it provides an apparatus and method for drying substrates. In one exemplary embodiment, drying of semiconductor wafers is described.

Substrate processing involves a wide variety of processing steps which form a substrate process flow. The substrate process flow may include, but is not limited to, forming layers, patterning layers, removing layers, planarizing layers, implanting species, etc. in and/or on the substrate, as is well known to those skilled in the art. At many points during a substrate process flow, the substrate needs to be dried. For example, many processing steps require the use of rinse and dry operations. At various stages of the substrate process flow, the substrate surface may have a wide range of exposed surface materials and patterns. A variety of techniques are known for use when drying the substrate at those various stages of processing, including but not limited to spin drying, vapor drying, isopropyl alcohol (IPA) drying, Marangoni drying, supercritical drying, etc.

Various problems have been found with the prior art techniques. For example in IPA drying, the last liquid step may include a fluid dispense and drying of the fluid. In one example of such drying, the last liquid step utilized may include a dispense of IPA and then the substrate may be rapidly spun while air/nitrogen is blown over the substrate to dry the IPA. However, such techniques may result in capillary pattern collapse in which patterns on the substrate are deformed or modified due to capillary stress effects. Such deformation and modification problems are particularly prevalent in high aspect ratio, small geometry structures. In another drying technique, supercritical drying with carbon dioxide may be used; however such techniques are slow and expensive.

As described herein, drying techniques are provided that avoid the pattern collapse of prior art techniques in a cost effective manner.

### SUMMARY OF THE INVENTION

A process and apparatus are provided in which substrate drying is accomplished by rapid boiling of the surface liquid to vaporize the liquid before it can cause capillary pattern collapse to occur. More specifically, electromagnetic induction heating is utilized to provide an oscillating magnetic field transverse to the substrate surfaces to induce electrical eddy currents in the substrate that cause the substrate to rapidly heat up. The liquid will then vaporize quickly without causing pattern collapse. Such techniques are particularly useful for IPA drying.

In one embodiment, a method of drying a substrate is described. The method may comprise providing a fluid on the substrate. The method may further comprise heating the substrate through the use of electromagnetic induction heating and removing the fluid from a surface of the substrate by the use of the electromagnetic induction heating.

In another embodiment, an apparatus for drying a substrate is provided. The apparatus may comprise a process chamber and a chuck for holding the substrate within the process chamber. The apparatus may further comprise an energy source and an energy transmitter coupled to the process chamber and the energy source, the energy transmitter configured to emit electromagnetic energy. The electromagnetic energy emitted from energy transmitter provides electromagnetic induction heating to the substrate by inducing a magnetic flux within the substrate so as to heat the substrate to provide a drying effect to the substrate.

In another embodiment, an apparatus for drying a substrate is provided. The apparatus may comprise a cylindrical process chamber, a chuck for holding the substrate within the cylindrical process chamber, a microwave energy source, and a magnetron coupled to the microwave energy source and the cylindrical process chamber, wherein energy from the magnetron may provide electromagnetic induction heating to the substrate.

In another embodiment, an apparatus for drying a substrate is provided. The apparatus may comprise a process chamber, an antenna extending into the process chamber, and a radio frequency (RF) source coupled to the antenna, wherein an RF magnetic flux excited with the antenna induces a magnetic flux within the substrate so as to heat the substrate to provide a substrate drying effect.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates one embodiment of a substrate dryer as described herein.

FIG. 2 illustrates another embodiment of a substrate dryer as described herein.

FIG. 3 illustrates a representation of magnetic field lines created by the dryer of FIG. 2.

FIG. 4 illustrates an exemplary method for utilizing the techniques described herein.

### DETAILED DESCRIPTION

A process and apparatus are provided in which substrate drying is accomplished by rapid boiling of the surface liquid to vaporize the liquid before it can cause capillary pattern collapse to occur. More specifically, electromagnetic induction heating is utilized to provide an oscillating magnetic field transverse to the substrate surfaces to induce electrical eddy currents in the substrate that cause the substrate to rapidly heat up. The liquid will then vaporize quickly without causing pattern collapse. Such techniques are particularly useful for IPA drying.

In one exemplary embodiment, the concepts described herein are described in the context of a substrate drying process that utilizes IPA. As will be recognized, however, that the concepts disclosed herein may be utilized with drying techniques that do not utilize IPA. Thus, the concepts described herein may be utilized in conjunction with other materials that are to be dried from a substrate. In that regard, having the benefit of the disclosure provided herein, it will be recognized that the techniques described herein may be utilized to heat a substrate in a wide range of drying applications. For example, the drying techniques described herein may be utilized when drying water from a substrate without the use of IPA.

As mentioned, in one exemplary embodiment, IPA may be applied to a substrate which is to be dried. In one embodiment, the IPA may be applied as a thick fluid layer of IPA that is dispensed on the substrate without spinning the substrate, ensuring that the entire top surface remains wetted with IPA. The techniques described herein are not, however, limited to non-spinning fluid applications of IPA. In the exemplary embodiment described, after application of IPA, the substrate is exposed to a magnetic flux. Due to Ampere's law and Faraday's law, this induces a current flow in the substrate. Due to ohmic collisions between electrons and the lattice, these electrical eddy currents are rapidly converted to thermal energy, causing an increase in the substrate temperature. In an exemplary embodiment, the substrate may be a semiconductor substrate, and in a more particular example, a silicon substrate, for example a silicon wafer. Equation 1 (provided below) describes the power absorption in the substrate for a substrate that is a silicon wafer. It will be recognized that other substrates may be utilized, providing differing power absorptions. The skin depth may be considered to be the depth into the substrate that the magnetic flux penetrates. The skin depth for a silicon wafer is given by Equation 2:

$$\begin{matrix}P = \frac{π {r}^{2} {t}^{3} ρ {H}_{0}^{2}}{{δ}^{4} + {t}^{4}} & Equation 1 \\ δ = \sqrt{\frac{2 ρ}{ωμ}} & Equation 2\end{matrix}$$

wherein
τ wafer radius [m]
t wafer thickness [m]
ρ Si resistivity [Ω·m]
δ skin depth [m]
H₀ magnetic field strength [A/m]
ω frequency [radians]
μ Si permeability [H/m]

Any of a wide variety of techniques may be used to provide the magnetic flux to the substrate. In one embodiment, a magnetron may be used. In another embodiment, an antenna may be utilized. Other techniques for providing magnetic flux to the system may also be utilized. In one embodiment, the substrate is exposed to an oscillating magnetic flux that is transverse to the wafer surface. The oscillating magnetic flux can have a frequency from less than 10 MHz to greater than 100 GHz. Due to the conductivity of the substrate and thickness of the substrate that is typically encountered for semiconductor wafers, this process may be more efficient at the higher frequency wavelengths. In one embodiment for use with semiconductor wafers, frequencies of 10 MHz to 100 GHz, or frequencies greater than 10 MHz may be used and in some embodiments 13.56 MHz to 2.45 GHz may be utilized, though such ranges are merely exemplary and other frequencies may be utilized. The magnetic flux results in magnetic induction heating of the substrate that may beneficially be utilized in drying the substrate. Thus, electromagnetic energy is utilized to achieve the electromagnetic induction heating to dry the substrate.

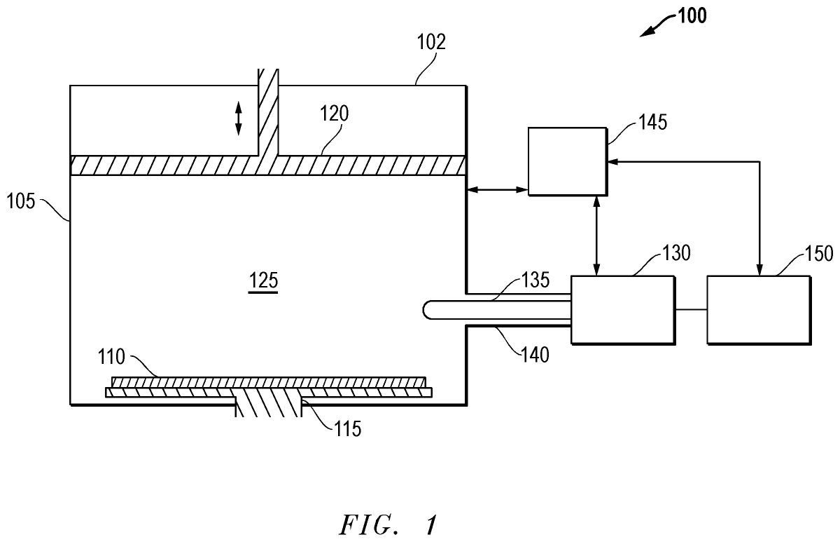

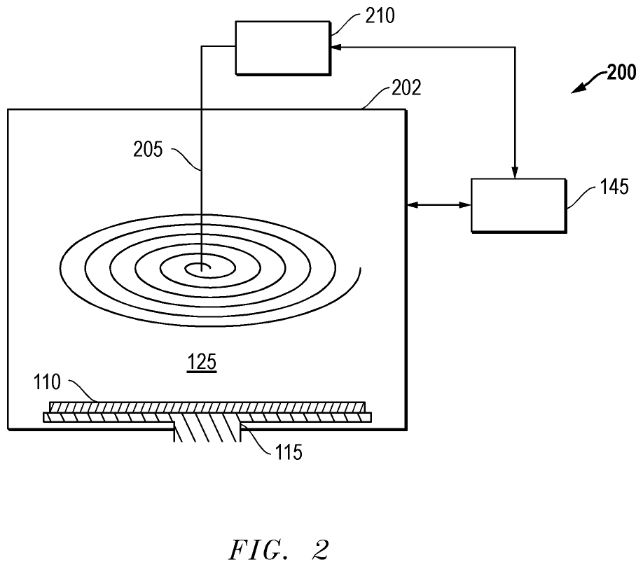

The drying techniques described herein are not limiting to a particular drying apparatus. FIGS. 1 and 2 provide two exemplary apparatus. However, a wide variety of other apparatus and techniques may be utilized to provide magnetic flux to the substrate. As shown in FIG. 1, a dryer 100 includes a process chamber 102 having chamber sidewalls 105, which in one embodiment may be cylindrical. A substrate 110 (for example a semiconductor wafer) may be held in place with a chuck 115 at the bottom of the process chamber 102. In one embodiment, the chuck 115 may be quartz. The chuck 115 may be configured to spin or may be configured not to spin. On one side of the process chamber 102, a waveguide 140 is connected to a magnetron 130 which is coupled to energy source 150 to provide the oscillating electromagnetic energy (for example microwave energy) into the process space 125. A radial tuner 135 may be provided to tune the frequency and phase of the electromagnetic energy provided from the magnetron 130.

The height of the process space 125 may be adjustable through the use of an adjustable top 120 which may move up and down as indicated in the figure. By adjusting the adjustable top 120, the volume of the process space 125 may be changed. The adjustable top 120 of the process chamber 102 is adjustable in height in order to tune the designed induction mode in the substrate 110. More specifically, the geometry of the chamber will affect the magnetic field lines in the wafer and the adjustable height may be utilized to tune these fields. Advantages of a dryer design such as the dryer 100 of FIG. 1 are that the dryer 100 enables a very high frequency to be used and the electromagnetic waves and flux can be fine-tuned to cause the desired induction modes (similar to vibration modes) in the substrate 110. In some embodiments of the apparatus of FIG. 1, the chamber may be large and it may be difficult to integrate such a design mechanically with other process tools due to the inherent features of such other tools such as liquid dispense arms, spin chuck, drain, etc. Thus, the embodiment of FIG. 1 may be more suited for being formed independently, though independent formation is not required. The dryer 100 may further include a controller 145 coupled to provide feedback and control to and from the process chamber 102 (and the various components within the process chamber 102, such as for example the adjustable top 120 and chuck 115), magnetron 130, energy source 150, radial tuner 135 and other components of the dryer 100. In one exemplary embodiment, the controller 145 may be a processor, microcontroller, or programmable logic device in combination with other circuitry such as memory, I/O ports, etc. In one embodiment, the processor, microcontroller or programmable logic device may be configured to execute instructions or configuration files to perform the induction heating functions described herein.

An alternative apparatus is shown in FIG. 2 of a dryer 200 having a process chamber 202. In the design of the dryer 200 of FIG. 2, there is an antenna 205 that is suspended above the wafer. The antenna 205 is connected to a power source 210, such as for example, an alternating current generator which operates at high frequencies. In one example, a spiral copper antenna may be utilized. In one embodiment, the antenna 205 can be embedded in a dielectric material. It will be recognized that a wide range of types of antennas and wide range of antenna designs may be utilized, as a spiral copper antenna is merely exemplary. Thus, a wide range of antenna shapes and designs may be utilized to provide electromagnetic energy to the dryer 200 and the particular embodiment shown is merely exemplary. As with the embodiment of FIG. 1, the controller 145 may provide feedback and control to and from the various components of the dryer 200 to perform the functions described herein.

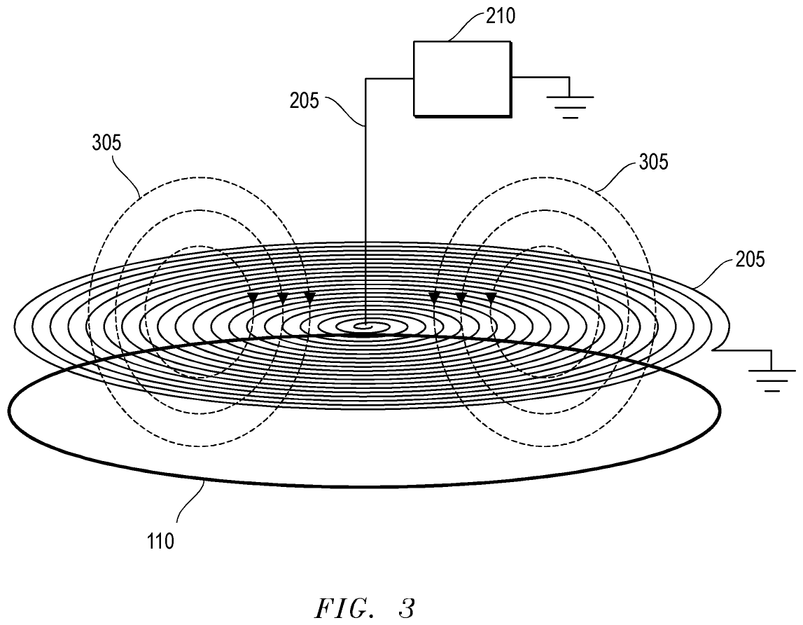

FIG. 3 provides a representation of the formation of magnetic field lines 305 to provide magnetic flux in the substrate 110 for the embodiment of FIG. 2. It will be recognized that the embodiment of FIG. 1 similarly will have magnetic fields which provide magnetic flux in the substrate 110. As shown in FIG. 3, the power source 210 and the antenna 205 generate magnetic field lines which extend to the substrate 110.

In the embodiment of FIG. 2, a radio frequency (RF) magnetic flux is excited with the antenna 205 above the substrate 110 (for example a silicon wafer) in order to induce the magnetic flux in the substrate. Such a design may be advantageous in that the design may be more easily integrated with the other mechanical apparatuses that are part of conventional substrate liquid processing tools: liquid stream dispense mechanisms, spray dispense mechanisms, drain mechanisms, spin chuck mechanisms, gas flow inlet and outlets, etc. For example, the antenna may be implemented in a manner that it may be moved up and out of the way during other processing steps. Thus, a retractable antenna may be provided to aid in integrating the dryer 200 in other liquid process tools. However, depending upon particular implementations of the designs of FIG. 1 and FIG. 2, the design of FIG. 2 may add difficulties in forming a uniform magnetic flux in the substrate, and the maximum frequency may be more limited than the dedicated cylindrical chamber approach. However, the magnetic flux uniformity may be improved by adapting the antenna design to a particular tool application.

In both cases of the dryers of FIGS. 1 and 2, an energy transmitter coupled to an energy source provides electromagnetic energy into the process chamber. In the case of FIG. 1, the waveguide and magnetron operate as a transmitter coupling electromagnetic energy into the process chamber. In the case of FIG. 2, the antenna 205 operates as an energy transmitter coupling electromagnetic energy into the process chamber. It will be recognized that many other energy transmitters may be utilized to couple electromagnetic energy into the process chamber so that electromagnetic induction heating heats a substrate as part of a substrate drying process.

Through the application of magnetic flux to the substrate (whatever technique is utilized), the substrate may rapidly heat up at a rate, in one exemplary embodiment, greater than 100° C./sec to a desired set temperature. Thus, magnetic induction heating may rapidly heat a substrate, such as for example a semiconductor wafer. In one example, the set temperature utilized for heating may be in a range of 200° C. to 500° C., or a range of 400° C. to 500° C. In some embodiments, a set temperature of 400° C. may be utilized. However, it will be recognized that the temperature utilized may be dependent upon what the substrate is formed of, what liquid is being dried from the substrate surface, the apparatus used to apply the magnetic flux, etc. This rapid heating causes the liquid that is touching the substrate surface to instantly boil, creating a thin vapor layer between the substrate and the rest of the liquid. Rapid boiling and the creation of a thin vapor layer is known as the Leidenfrost effect, and will cause the remaining liquid to flow off the substrate surface because it is now floating on an effectively frictionless surface of the substrate. The flow of the liquid off the substrate surface may be aided by spinning the substrate, though spinning is not required. Thus, induction heating may advantageously utilize the Leidenfrost effect to provide drying to the substrate. With all the liquid either vaporized or flowed off the surface, the substrate is completely dry and has no danger of deformation of structures or modification of structures due to capillary forces. The substrate can then be removed from the drying equipment for subsequent processing steps. In the case of IPA, the rapid boiling creates a thin IPA vapor layer and the IPA is either vaporized or flows off the substrate surface.

As described herein, the drying techniques may be utilized at any of a wide variety of process steps utilized in a substrate process flow. In one embodiment, the substrate may be a semiconductor wafer. The drying techniques can be implemented at any number of process steps including back end of line and front end of line semiconductor wafer process steps.

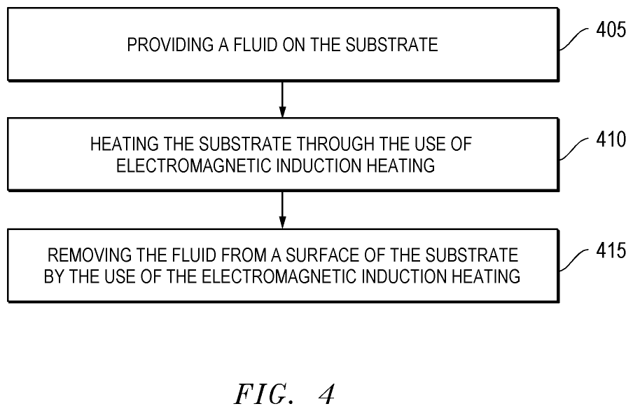

It will be recognized that the methods described above are merely exemplary, and many other processes and applications may advantageously utilize the techniques disclosed herein. FIG. 4 illustrates an exemplary method for use of the processing techniques described herein. It will be recognized that the embodiment of FIG. 4 is merely exemplary and additional methods may utilize the techniques described herein. Further, additional processing steps may be added to the method shown in the FIG. 4 as the steps described are not intended to be exclusive. Moreover, the order of the steps is not limited to the order shown in the figures as different orders may occur and/or various steps may be performed in combination or at the same time.

In FIG. 4, a method of drying a substrate is shown. The method may comprise step 405 of providing a fluid on the substrate. The method may further comprise step 410 of heating the substrate through the use of electromagnetic induction heating. The method also comprises step 415 of removing the fluid from a surface of the substrate by the use of the electromagnetic induction heating.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A method of drying a substrate, the method comprising:
providing a fluid on the substrate;
heating the substrate through the use of electromagnetic induction heating; and
removing the fluid from a surface of the substrate by the use of the electromagnetic induction heating.

2. The method of claim 1, wherein the removing the fluid occurs before capillary pattern collapse on the substrate occurs.

3. The method of claim 1, wherein the substrate is a semiconductor wafer.

4. The method of claim 3, wherein electromagnetic energy having frequencies of greater than 10 MHz is utilized to achieve the electromagnetic induction heating.

5. The method of claim 4, wherein the fluid is isopropyl alcohol (IPA).

6. The method of claim 5, wherein the electromagnetic induction heating heats the substrate to a temperature in a range of 400° C. to 500° C.

7. The method of claim 1, wherein the fluid is isopropyl alcohol (IPA).

8. The method of claim 7, wherein the electromagnetic induction heating heats the substrate to a temperature in a range of 400° C. to 500° C.

9. The method of claim 7, wherein a magnetron is used for the electromagnetic induction heating.

10. The method of claim 7, wherein an antenna is used for the electromagnetic induction heating.

11. The method of claim 7, wherein a controller is configured to control a magnetic flux within the substrate in order to avoid deformation or modification of structures in the substrate due to capillary stress effects.

12. An apparatus for drying a substrate comprising:
a process chamber;
a chuck for holding the substrate within the process chamber;
an energy source; and
an energy transmitter coupled to the process chamber and the energy source, the energy transmitter configured to emit electromagnetic energy,
wherein the electromagnetic energy emitted from energy transmitter provides electromagnetic induction heating to the substrate by inducing a magnetic flux within the substrate so as to heat the substrate to provide a drying effect to the substrate.

13. The apparatus of claim 12, wherein a volume of the process chamber is adjustable.

14. The apparatus of claim 13, wherein the top of the process chamber is adjustable.

15. The apparatus of claim 12, wherein the energy transmitter is a magnetron.

16. The apparatus of claim 12, wherein the energy transmitter is an antenna.

17. The apparatus of claim 16, wherein the antenna is retractable.

18. The apparatus of claim 17, wherein the apparatus is a substrate liquid processing tool.

19. The apparatus of claim 12, wherein the electromagnetic energy has a frequency in a range of 10 MHz to 100 GHz.

20. The apparatus of claim 19 further comprising a controller configured to control the magnetic flux within the substrate in order to avoid deformation of structures in the substrate or modification of the structures due to capillary stress effect.
